(19) United States
(12) Patent Application Publication
(10) Pub. No.: US 2025/0278105 A1
(43) Pub. Date: Sep. 4, 2025

(54) Regulator Circuit, Circuit Device, And Oscillator

(71) Applicant: SEIKO EPSON CORPORATION, Tokyo (JP)

(72) Inventors: Wataru OKUMURA, Minowa (JP); Akio TSUTSUMI, Chino (JP); Ryo ICHIKAWA, Minamiminowa (JP)

(21) Appl. No.: 19/065,357

(22) Filed: Feb. 27, 2025

(30) Foreign Application Priority Data
Feb. 29, 2024 (JP) 2024-029445

(51) Int. Cl. G05F 1/575; G06F 1/08; H03H 11/12

(52) U.S. Cl. CPC G05F 1/575; G06F 1/08; H03H 11/1213

(57) ABSTRACT

A regulator circuit includes an N-type output transistor provided between a first power supply node and an output node of a regulated voltage, an operational amplifier having a first input terminal to which a reference voltage is input and a second input terminal to which a feedback voltage based on the regulated voltage is input, and a low-pass filter circuit outputting a drive voltage obtained by filtering an output voltage of the operational amplifier to a gate of the output transistor. The low-pass filter circuit includes a MOS capacitor provided between the gate of the output transistor and a second power supply node and including a transistor having a withstand voltage lower than that of the output transistor.

The present application is based on, and claims priority from JP Application Serial Number 2024-029445, filed Feb. 29, 2024, the disclosure of which is hereby incorporated by reference herein in its entirety.

### BACKGROUND

### 1. Technical Field

The present disclosure relates to a regulator circuit, a circuit device, an oscillator, and the like.

### 2. Related Art

In related art, a regulator circuit that steps down a power supply voltage to generate a regulated voltage is known. For example, WO 2014/207969 discloses a regulator circuit including an operational amplifier having one input terminal to which a reference voltage is input and the other input terminal to which a feedback voltage is input, and a source-follower coupled output transistor having a gate to which an output signal of the operational amplifier is input and provided between a power supply node and an output node.

WO 2014/207969 is an example of the related art.

It is considered that a low-pass filter circuit having a capacitor is provided to reduce noise in a regulator circuit as in WO 2014/207969. When a MOS capacitor including a MOS transistor is used as the capacitor, to increase the withstand voltage, the gate oxide film thickness of the MOS capacitor increases and the capacitance value per unit area decreases. Therefore, there is a problem that a capacitor having a larger circuit area is required to secure a necessary capacitance value.

### SUMMARY

An aspect of the present disclosure relates to a regulator circuit including an N-type output transistor provided between a first power supply node and an output node of a regulated voltage, an operational amplifier having a first input terminal to which a reference voltage is input and a second input terminal to which a feedback voltage based on the regulated voltage is input, and a low-pass filter circuit outputting a drive voltage obtained by filtering an output voltage of the operational amplifier to a gate of the output transistor, wherein the low-pass filter circuit includes a MOS capacitor provided between the gate of the output transistor and a second power supply node and including a transistor having a withstand voltage lower than that of the output transistor.

Another aspect of the present disclosure relates to a circuit device including a power supply circuit including the above described regulator circuit, an oscillation circuit oscillating a resonator, and a clock signal generation circuit generating a clock signal based on an oscillation clock signal from the oscillation circuit.

Another aspect of the present disclosure relates to an oscillator including the above described circuit device, and the resonator.

### BRIEF DESCRIPTION OF THE DRAWINGS

FIG. 1 shows a configuration example of a regulator circuit according to an embodiment.

FIG. 2 shows a configuration example of a regulator circuit provided with an analog switch.

FIG. 3 shows a configuration example of the analog switch.

FIG. 4 shows a configuration example of a feedback circuit.

FIG. 5 shows characteristic examples of a current flowing through an output transistor and a drive voltage input to a gate.

FIG. 6 shows characteristic examples of a PSRR of the regulator circuit.

FIG. 7 shows another configuration example of the regulator circuit.

FIG. 8 shows a configuration example of a circuit device including the regulator circuit and an oscillator including the circuit device.

FIG. 9 shows a configuration example of a PLL circuit as an example of a clock signal generation circuit.

### DESCRIPTION OF EMBODIMENTS

As below, an embodiment will be described. The embodiment to be described below does not unduly limit the description of the claims. Not all configurations described in the embodiment are essential component elements.

### 1. Regulator Circuit

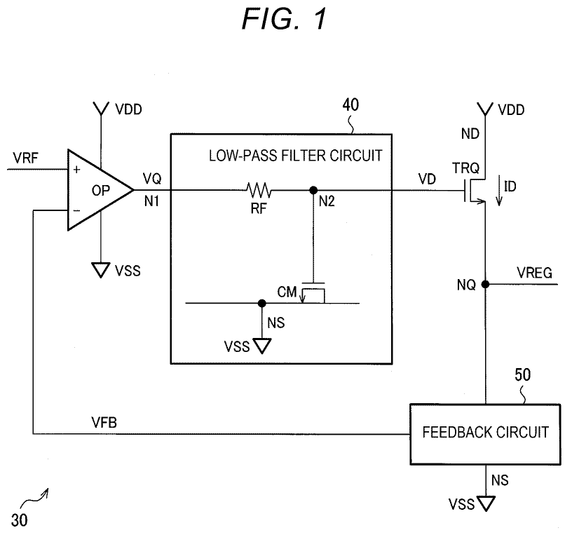

FIG. 1 shows a configuration example of a regulator circuit 30 of the embodiment. The regulator circuit 30 includes an output transistor TRQ, an operational amplifier OP, and a low-pass filter circuit 40. The regulator circuit 30 can include a feedback circuit 50. The regulator circuit 30 is a circuit that steps down a power supply voltage VDD to generate a regulated voltage VREG. The regulator circuit 30 is not limited to the configuration in FIG. 1, but various modifications such that a part of the component elements is omitted, another component element is added, and a part of the component elements is replaced by another component element can be made.

The output transistor TRQ is, for example, an N-type transistor, and specifically, an N-type MOS (Metal Oxide Semiconductor) transistor. The N-type output transistor TRQ is provided between a first power supply node ND and an output node NQ of the regulated voltage VREG. The first power supply node ND is a node to which the VDD is supplied, and is, for example, a power supply node at a high-potential side. The output node NQ is a node from which the regulated voltage VREG is output. For example, the output transistor TRQ has a drain coupled to the first power supply node ND and a source coupled to the output node NO of the regulated voltage VREG. A drive voltage VD is input to a gate of the output transistor TRQ. The drive voltage VD is a voltage obtained by filtering of an output voltage VQ of the operational amplifier OP by the low-pass filter circuit 40. As described above, the output transistor TRQ is the source-follower coupled N-type transistor, and the regulated voltage VREG changes to follow the drive voltage VD. For example, when the drive voltage VD rises, the regulated voltage VREG also rises, and when the drive voltage VD falls, the regulated voltage VREG also falls.

In the embodiment, for example, a depression-type N-type transistor having a negative threshold voltage is used as the output transistor TRQ. However, an enhancement-type N-type transistor having a positive threshold voltage may be used as the output transistor TRQ.

The operational amplifier OP has a first input terminal to which a reference voltage VRF is input and a second input terminal to which a feedback voltage VFB based on the regulated voltage VREG is input. The first input terminal is, for example, a non-inverting input terminal of the operational amplifier OP, and the second input terminal is, for example, an inverting input terminal of the operational amplifier OP. The reference voltage VRF input to the first input terminal of the operational amplifier OP is generated by a reference voltage generation circuit (not shown). The reference voltage generation circuit is realized by, for example, a bandgap reference circuit. The feedback voltage VFB input to the second input terminal of the operational amplifier OP is generated by the feedback circuit 50. As described above, in the operational amplifier OP operating as an error amplifier, the reference voltage VRF is input to the first input terminal, the feedback voltage VFB is input to the second input terminal, and the output voltage VQ is output from the output terminal.

The low-pass filter circuit 40 performs low-pass filtering on the output voltage VQ of the operational amplifier OP. For example, the low-pass filter circuit 40 outputs the drive voltage VD obtained by filtering the output voltage VQ of the operational amplifier OP to the gate of the output transistor TRQ. The low-pass filter circuit 40 includes a resistor RF and a MOS capacitor CM. Thus, the low-pass filter circuit 40 is an RC filter including the resistor RF and the MOS capacitor CM.

The resistor RF is provided between the output terminal of the operational amplifier OP and the gate of the output transistor TRQ. For example, one end of the resistor RF is coupled to a node N1 of the output terminal of the operational amplifier OP, and the other end is coupled to a node N2 of the gate of the output transistor TRQ.

The MOS capacitor CM is a capacitor including a MOS (Metal Oxide Semiconductor) transistor, and the capacitance of the MOS capacitor CM is the gate capacitance of the MOS transistor. The MOS capacitor CM is provided between the gate of the output transistor TRQ and a second power supply node NS. For example, in the MOS capacitor CM, the gate of the transistor forming the CM is coupled to the node N1 of the gate of the output transistor TRQ, and the source and the drain are coupled to the second power supply node NS. The second power supply node NS is, for example, a node to which VSS is supplied, and is, for example, a power supply node at a low-potential side. VSS may also be referred to as ground GND. The second power supply node NS may be a node at a predetermined potential, not the power supply node at VSS.

The feedback circuit 50 is provided between the output node NQ of the regulated voltage VREG and the second power supply node NS, and outputs the feedback voltage VFB. For example, the feedback circuit 50 as a voltage divider circuit outputs a voltage obtained by division of the regulated voltage VREG as the feedback voltage VFB. For example, the feedback circuit 50 includes a ladder resistor circuit having a plurality of resistors coupled in series between the output node NQ and the second power supply node NS, and outputs a voltage of a given voltage division node of the ladder resistor circuit as the feedback voltage VFB.

In the embodiment, the low-pass filter circuit 40 includes the MOS capacitor CM provided between the gate of the output transistor TRQ and the second power supply node NS and includes the transistor having a lower withstand voltage than the output transistor TRQ. For example, the output transistor TRQ is a transistor having a first withstand voltage, whereas the MOS capacitor CM includes a transistor having a second withstand voltage lower than the first withstand voltage. The first withstand voltage as a high withstand voltage is, for example, about 4 V to 7 V, and is, for example, about 5.5 V. The second withstand voltage as a low withstand voltage is, for example, about 1.5 V to 2 V, and is, for example, about 1.8 V. The withstand voltage is, for example, a rated voltage of a transistor. For example, the gate oxide film thickness of the transistor forming the MOS capacitor CM is smaller than the gate oxide film thickness of the output transistor TRQ.

In the embodiment, the RC low-pass filter circuit 40 is provided in the regulator circuit 30 for realization of noise reduction of the regulated voltage VREG generated by the regulator circuit 30. The regulator circuit 30 includes the operational amplifier OP as an error amplifier that compares the reference voltage VRF as a constant voltage with the feedback voltage VFB, the low-pass filter circuit 40 for reducing noise, and the output transistor TRQ as, for example, a depression-type N-type MOSFET for increasing the strength against disturbance noise.

In this case, in the technique of the comparative example, as the RC low-pass filter circuit 40, for example, an MIM (Metal-Insulator-Metal) capacitor or a MOS capacitor having a withstand voltage corresponding to the maximum power supply voltage is used. However, generally, the higher the withstand voltage, the larger the gate oxide film thickness of the MOS capacitor and the smaller the capacitance value per unit area. Therefore, in order to secure a necessary capacitance value, it is necessary to prepare a MOS capacitor having a large size (circuit area). For example, it is necessary to increase the gate width W and the gate length L of the MOS transistor forming the MOS capacitor, and a problem arises in that the layout area of the circuit increases.

In this regard, in the embodiment, the low-voltage MOS capacitor CM is used as the capacitor of the low-pass filter circuit 40. The low-voltage MOS capacitor CM has the smaller gate oxide film thickness than a high-voltage MOS capacitor, and has a larger capacitance value per unit area. Therefore, even when the size of the MOS transistor forming the MOS capacitor CM is reduced, a necessary capacitance value can be secured, and the circuit area of the regulator circuit 30 can be reduced. Accordingly, both noise reduction and circuit area reduction can be realized.

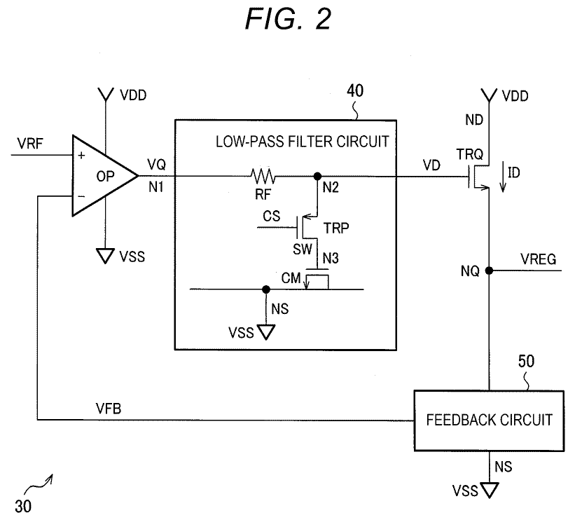

On the other hand, when the low-voltage MOS capacitor CM is used, a situation in which a voltage exceeding the withstand voltage of the MOS capacitor CM is applied to the gate of the transistor of the MOS capacitor CM may occur. In order to protect the low-voltage MOS capacitor CM in the situation, an analog switch SW is provided in series to the MOS capacitor CM in configuration example of FIG. 2.

That is, in FIG. 2, the low-pass filter circuit 40 has the analog switch SW provided between the gate of the output transistor TRQ and the gate of the MOS capacitor CM. For example, one end of the analog switch SW is coupled to the node N2 of the gate of the output transistor TRQ, and the other end is coupled to a node N3 of the gate of the MOS capacitor CM. The analog switch SW is turned on and off by a control signal CS. The control signal CS is generated by, for example, a control circuit of the circuit device including the regulator circuit 30. For example, in a situation in which a voltage exceeding the gate withstand voltage is applied to the gate of the low-voltage MOS capacitor CM, the analog switch SW is turned off by a control signal CS. Thereby, the high voltage of the node N2 is not applied to the gate of the MOS capacitor CM, and the MOS capacitor CM can be protected.

For example, the regulator circuit 30 of the embodiment has a normal operation mode and a test mode. The normal operation mode is a mode in which the circuit device having the regulator circuit 30 normally operates and the analog switch SW is turned on in the normal operation mode. As a result, the RC low-pass filter circuit 40 including the resistor RF and the MOS capacitor CM is realized, low-pass filtering is performed on the output voltage VQ of the operational amplifier OP, and noise reduction of the regulated voltage VREG is realized. The test mode is an inspection mode, for example, a mode set at the time of manufacturing or shipping inspection of the circuit device including the regulator circuit 30. In the test mode, the analog switch SW is turned off. As a result, although the MOS capacitor CM does not function as a capacitor of the low-pass filter circuit 40, the analog switch SW is turned off, and thereby, transfer of the drive voltage VD of the node N2 to the gate of the MOS capacitor CM is blocked and the MOS capacitor CM can be protected from a high voltage. The test mode will be described in detail later.

When it can be ensured that there is no situation of the exceeding withstand voltage of the MOS capacitor CM, the analog switch SW is not necessarily provided, and the configuration of FIG. 1 can be employed.

In FIG. 2, the analog switch SW is realized by a P-type transistor TRP. For example, the source of the P-type transistor TRP as the analog switch SW is coupled to the node N2 of the drive voltage VD, and the drain is coupled to the node N3 of the gate of the MOS capacitor CM. The control signal CS for turning on or off the analog switch SW is input to the gate of the P-type transistor TRP. As described above, the P-type transistor TRP is used as the analog switch SW, and thereby, the deterioration of an operating point and noise can be suppressed, and the deterioration of a phase margin and a PSRR (Power Supply Rejection Ratio) can be suppressed.

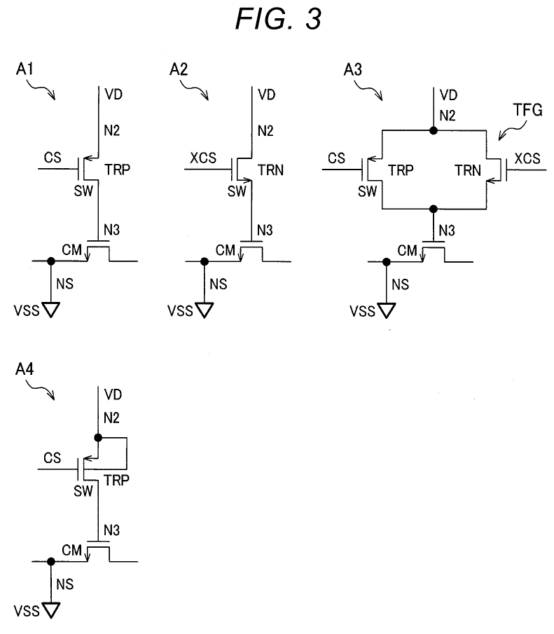

For example, FIG. 3 shows various configuration examples of the analog switch SW. As the analog switch SW, the P-type transistor TRP shown by A1, an N-type transistor TRN shown by A2, a transmission gate TFG shown by A3, or the like can be used. The transmission gate TFG includes the P-type transistor TRP and the N-type transistor TRN coupled in parallel.

For example, in the regulator circuit 30 of FIG. 2, when an on resistance of the analog switch SW increases, the phase margin of the regulator circuit 30 deteriorates. When the phase margin of the regulator circuit 30 deteriorates, the regulated voltage VREG as the output voltage of the regulator circuit 30 becomes unstable. That is, when the phase margin decreases, the regulated voltage VREG takes time to converge and becomes unstable, and may oscillate depending on conditions.

On the other hand, when W/L of the transistor of the analog switch SW is increased in order to reduce the on resistance of the analog switch SW, L×W as the gate area increases and the leakage current flowing through the back gate increases. When electric charge is extracted from the node N2 of the drive voltage VD due to a larger amount of the leakage current to the back gate, the voltage of the node N2 decreases, which leads to deterioration of the operating point and deterioration of noise. That is, deterioration of the operating point such that the output transistor TRQ does not operate in the saturation region or the operational amplifier OP does not operate in an appropriate operating range occurs, and noise of the regulated voltage VREG also increases.

When the transmission gate TFG as shown by A3 of FIG. 3 is used as the analog switch SW, there are two leakage current paths, and the amount of leakage current increases. Therefore, in order to suppress the deterioration of the operating point and the noise due to the leakage current, it is desirable to use the P-type or N-type one-side channel transistor as the analog switch SW as shown by A1 and A2.

The leakage current can be reduced by short-circuiting of the back gate of the transistor to the source. That is, the leak current flowing from the node N2 of the drive voltage VD to the substrate can be reduced, and the deterioration of the operating point and noise, and the like due to the leakage current can be reduced. In this case, when a P-type substrate is used as a substrate on which the transistor is formed, a triple-well structure is required to couple the back gate of the N-type transistor TRN of A2 in FIG. 3 to a device other than the power supply. For example, when the triple well structure is not used, a leakage current flows from the N-type impurity region of the drain of the N-type transistor TRN to the P-type substrate set at VSS. However, the triple-well structure causes an increase in circuit area, an increase in manufacturing cost, and the like. Accordingly, it is desirable to use the P-type transistor TRP as shown by A1 of FIG. 3 as the analog switch SW. Further, it is desirable to couple the back gate of the P-type transistor TRP to the source as shown by A4 in FIG. 3.

As described above, the P-type transistor TRP or the N-type transistor TRN as shown by A1 or A2 is used instead of the transmission gate TFG as shown by A3 of FIG. 3 as the analog switch SW, and thereby, the leakage current can be reduced into the single path, and the deterioration of the operation point and noise due to the leakage current can be suppressed.

When the P-type transistor TRP as shown by A1 of FIG. 3 is used as the analog switch SW, the leakage current can be prevented from flowing to the substrate via the back gate without using a triple-well structure or the like. For example, as shown by A4 of FIG. 3, the back gate of the P-type transistor TRP is coupled to the source. For example, the back gate of the P-type transistor TRP is coupled to the node N2 as the source node of the P-type transistor TRP. According to the configuration, the leakage current of the P-type transistor TRP can be reduced, and variations of the drive voltage VD due to the leakage current can be suppressed. As a result, the deterioration of the operating point of the regulator circuit 30 and the deterioration of noise, and the like due to the variations of the drive voltage VD can be suppressed. For example, when a triple-well structure is employed or the polarity of the substrate is different, a modification using the N-type transistor TRN as the analog switch SW can be made. In this case, the back gate of the N-type transistor TRN may be coupled to, for example, the source.

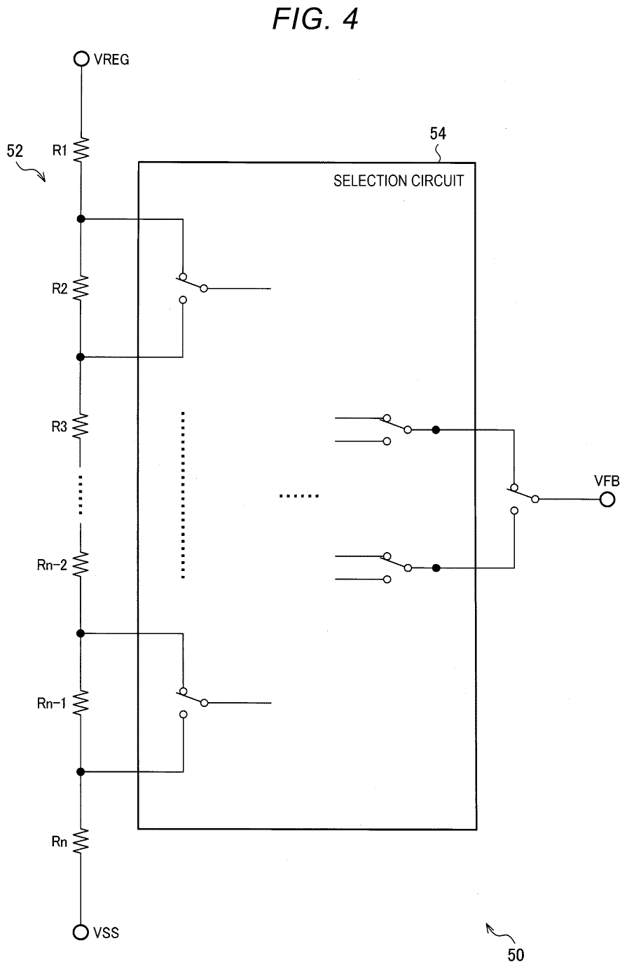

FIG. 4 shows a configuration example of the feedback circuit 50. The feedback circuit 50 includes a ladder resistance circuit 52 and a selection circuit 54. The ladder resistance circuit 52 includes a plurality of resistors R1 to Rn provided in series between the node of the regulated voltage VREG and the node of VSS. The selection circuit 54 selects one of a plurality of divided voltages from plurality of voltage division nodes (resistance division nodes) by the plurality of resistors R1 to Rn of the ladder resistance circuit 52, and outputs the selected divided voltage as the feedback voltage VFB. For example, the selection circuit 54 includes a plurality of selectors as shown in FIG. 4, and outputs a divided voltage selected by the plurality of selectors in a tournament manner as the feedback voltage VFB. The control signals for the plurality of selectors are output by the control circuit of the circuit device. For example, in the ladder resistor circuit 52, the value of the resistance from the voltage division node of the divided voltage selected by the selection circuit 54 to the node of VSS is RA, and the value of the resistance from the node of the regulated voltage VREG to the voltage division node is RB. The regulated voltage can be expressed as VREG=VRF×{(RA+RB)/RB}. As will be described later, in the test mode, the regulator circuit 30 outputs the regulated voltage VREG for the test mode, which is higher than the regulated voltage VREG for the normal operation mode. As an example, the regulator circuit 30 outputs a regulated voltage VREG of, for example, 1.5 V in the normal operation mode, and outputs a regulated voltage VREG of, for example, 3 V or 2.5 V in the test mode. The voltage of 3 V or 2.5 V is higher than the withstand voltage of the MOS capacitor CM, for example. The feedback circuit 50 of FIG. 4 can output the regulated voltage VREG for the normal operation mode in the normal operation mode and can output the regulated voltage VREG for the test mode in the test mode by switching control of the selector of the selection circuit 54.

In the embodiment, the low-resistance voltage MOS capacitor CM is used for the low-pass filter circuit 40 of the regulator circuit 30, and thereby, the circuit is reduced. In this case, the drive voltage VD at the node of the gate of the output transistor TRQ is expressed by the following expression (1).

$$VD = VREG + VGS \qquad ( 1 )$$

That is, since the N-type output transistor TRQ is source-follower coupled, the drive voltage VD is a voltage obtained by addition of a gate-source voltage VGS of the output transistor TRQ to the regulated voltage VREG. The gate-source voltage VGS of the output transistor TRQ is expressed by the following expression (2) from the formula of the MOS transistor in the saturation region.

$$VGS = \sqrt{\frac{2 ID}{μ C \frac{W}{L}}} + VTH \qquad ( 2 )$$

In the expression (2), ID is a drain current flowing through the output transistor TRQ, and μ is an amount of carrier transfer of the output transistor TRQ. C is capacitance of the gate oxide film of the output transistor TRQ, and VTH is a threshold voltage of the output transistor TRQ. W and L are a gate width and a gate length of the output transistor TRQ, respectively. Accordingly, the drive voltage VD is expressed by the following expression (3) from the expressions (1) and (2).

$$VD = VREG + \sqrt{\frac{2 ID}{μ C \frac{W}{L}}} + VTH \qquad ( 3 )$$

For example, when a depression-type N-type transistor is used as the output transistor TRQ, the threshold voltage VTH becomes a negative voltage. Accordingly, for example, when VREG=1.5 V and VTH=−0.4 V, from the above expression (3), the drive voltage VD of the node N2 gradually rises from about 1.5 V−0.4 V=1.1 V according to the current ID flowing through the load.

For example, as a comparative example of the embodiment, there is a technique using a P-type transistor as the output transistor TRQ. In the technique of the comparative example, the drive voltage VD of the node N2 becomes a voltage close to VDD as the power supply voltage at the high-potential side. Therefore, the low-voltage MOS capacitor CM cannot be used for the low-pass filter circuit 40, and the circuit area increases.

In this regard, since the source-follower coupled N-type transistor is used as the output transistor TRQ in the embodiment, as shown in the above expression (1), the drive voltage VD becomes a voltage obtained by addition of the gate-source voltage VGS to the regulated voltage VREG. Accordingly, the drive voltage VD can be set to a lower voltage than that when a P-type transistor is used as in the technique of the comparative example. Therefore, a low-voltage MOS capacitor CM can be used, and the circuit area can be reduced. In particular, when a depression-type N-type transistor is used as the output transistor TRQ, the threshold voltage VTH becomes a negative voltage. Accordingly, as is clear from the expression (3), the drive voltage VD can be further lowered compared to a case of using an enhancement-type N-type transistor, and it becomes easier to use a low-voltage MOS capacitor CM for the low-pass filter circuit 40.

In the embodiment, the regulator circuit 30 has the test mode other than the normal operation mode in which the circuit device is normally operated. For example, in the normal operation mode, the regulated voltage VREG is set to, for example, 1.5 V, however, in the test mode as the inspection mode, the regulated voltage VREG is set to, for example, 3 V or 2.5 V. The analog switch SW as shown in FIG. 2 is provided for the test mode, and the analog switch SW is turned off in the test mode to prevent application of a high voltage to the gate of the low-voltage MOS capacitor.

For example, the regulated voltage VREG from the regulator circuit 30 is supplied to the respective circuits of the circuit device, and these circuits operate using the regulated voltage VREG as a power supply voltage. Further, these circuits include low-voltage transistors in order to enable high-speed operation and realize low power consumption. Accordingly, in order to remove an initial failure and improve reliability, a test of applying a voltage of, for example, 3 V to the low-voltage transistors of these circuits is performed. The application test of 3 V or the like is generally called a screening test for removing an initial failure. When the application test is performed for a longer time, the product is deteriorated, and when the application test is performed only for a shorter time, a defective product is overlooked. Accordingly, test conditions including a voltage, a temperature, and the like are set with respect to each product. For example, in the embodiment, the application test of 3 V is performed in a condition such that the initial failure can be appropriately removed without application for a longer time causing the quality deterioration or breakdown. In this case, in addition to the voltage application of 3 V, for example, a high temperature of 100° C. or more is set to maximize the load current, and a load is applied by the maximum operation. Accordingly, the drive voltage VD of the node N2 may be equal to or higher than an allowable voltage of 3 V. Therefore, in the embodiment, the analog switch SW is provided in the low-pass filter circuit 40, and the analog switch SW is turned off at the time of testing to prevent application of a voltage of 3 V or more to the low-voltage MOS capacitor CM. Note that the application mode of 2.5 V is used in a reliability test.

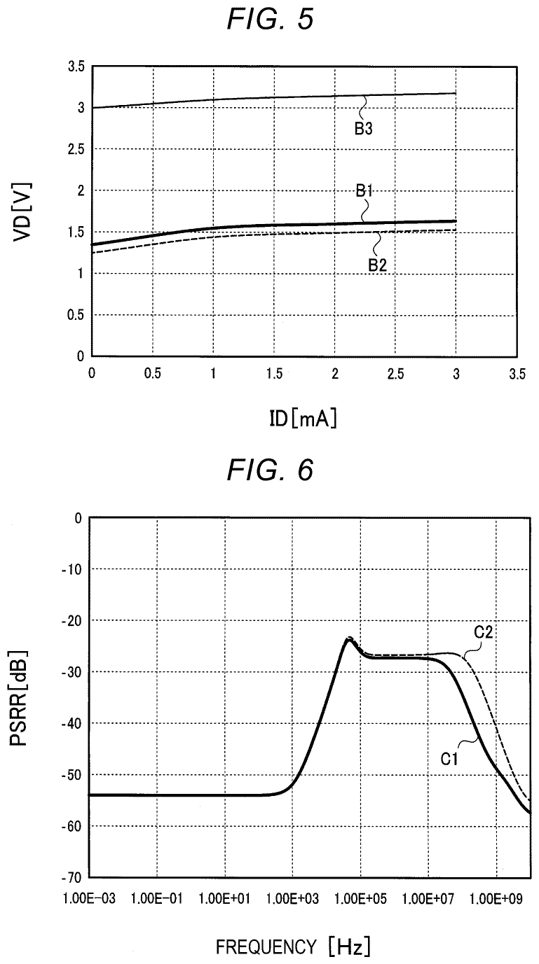

FIG. 5 shows characteristic examples of the current ID flowing through the output transistor TRQ and the drive voltage VD. B1 in FIG. 5 shows the characteristic example when the regulated voltage is VREG=1.5 V and the power supply voltage is VDD=5.5 V, and B2 shows the characteristic example when the regulated voltage is VREG=1.5 V and the power supply voltage is VDD=2.25 V. B3 shows the voltage characteristic when the regulated voltage is VREG=3 V and the power supply voltage is VDD=5.5 V. As shown in the expression (3), the drive voltage VD gradually rises according to the current ID as the load current of the circuit as the supply destination of the regulated voltage VREG from the output transistor TRQ. The load current of the circuit as the supply destination of the regulated voltage VREG is known in design or the like. Accordingly, in B1 and B2 of FIG. 5, for example, the W/L of the output transistor TRQ in the expression (3) is set so that the withstand voltage of the MOS capacitor CM is not exceeded even when the load current becomes the maximum. Thereby, when the analog switch SW is turned on in the normal operation mode, application of a voltage exceeding the withstand voltage to the low-voltage MOS capacitor CM is prevented.

On the other hand, in the test mode, since the drive voltage VD becomes 3 V or more as shown by B3 in FIG. 5, the voltage applied to the gate of the MOS capacitor CM is outside the allowable range in the screening test, for example. Accordingly, in FIG. 2, the analog switch SW is provided and the analog switch SW is turned off in the test mode to prevent application of a voltage beyond the allowable range to the low-voltage MOS capacitor CM. As a result, higher speed, lower power consumption, and the like of the circuit supplied with the regulated voltage VREG can be realized, and application of a voltage exceeding the withstand voltage to the MOS capacitor CM can be prevented. Further, the low-voltage MOS capacitor CM is used, and thereby, the circuit area can be reduced compared to a case using a high-voltage MOS capacitor. As an example, in a high-voltage MOS capacitor, for example, L=7 μm, W=900 μm, and the gate area is 7 μm×900 μm, whereas in a low-voltage MOS capacitor CM, L=4 μm, W=600 μm, and the gate area is 4 μm×600 μm. The film thickness of the low-voltage MOS capacitor CM is, for example, about one-third to one-fourth of the film thickness of the high withstand voltage MOS capacitor. Therefore, in the low-voltage MOS capacitor, even when the gate area is reduced to 4 μm×600 μm, about 40% of the high-voltage MOS capacitor, the capacitance value required for the low-pass filtering of the low-pass filter circuit 40 can be secured. Accordingly, both noise reduction in the regulated voltage VREG and circuit area reduction can be realized.

For example, the regulated voltage is VREG, the gate-source voltage of the output transistor TRQ is VGS, the withstand voltage of the MOS capacitor CM is VMOS, and the withstand voltage of the analog switch SW is VSW. In this case, in the normal operation mode of the regulator circuit 30, the analog switch SW is turned on. Then, a relationship of VREG+VGS<VMOS holds. For example, in B1 and B2 of FIG. 5, the drive voltage VD=VREG+VGS is smaller than the withstand voltage VMOS of the MOS capacitor CM. Thereby, application of a voltage exceeding the withstand voltage to the gate of the MOS capacitor CM can be prevented. On the other hand, in the test mode, the analog switch SW is turned off. Then, a relationship of VMOS<VREG+VGS<VSW holds. For example, in B3 of FIG. 5, VD=VREG+VGS is larger than the withstand voltage VMOS of the MOS capacitor CM, however, the analog switch SW is turned off and application of a voltage exceeding the withstand voltage to the gate of the MOS capacitor CM can be prevented. The drive voltage VD=VREG+VGS is smaller than the withstand voltage VSW of the analog switch SW. Accordingly, application of a voltage exceeding the withstand voltage to the analog switch SW can be prevented.

In addition, when the analog switch SW is provided, in the normal operation mode, characteristics of the regulator circuit 30 may be deteriorated due to the leakage current, the on resistance, or the like of the analog switch SW. In this regard, in FIG. 2, the P-type transistor TRP is used as the analog switch SW. The P-type transistor TRP is used, and thereby, the leakage current is reduced and deterioration of the operating point and noise, deterioration of the PSRR, and the like can be suppressed. For example, C1 in FIG. 6 is a characteristic example of the PSRR when the P-type transistors TRP of A1 or A4 in FIG. 3 is used as the analog switch SW, and C2 in FIG. 6 is a characteristic example of the PSRR when the transmission gate TFG of A3 in FIG. 3 is used. As shown in FIG. 6, when the P-type transistor TRP is used as the analog switch SW, the characteristics of the PSRR are better at the high-frequency side of, for example, 10 MHz or more.

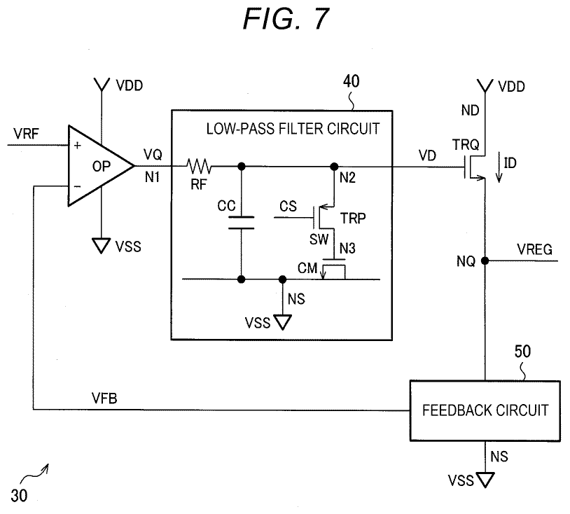

FIG. 7 shows another configuration example of the regulator circuit 30. In FIG. 7, a capacitor CC for phase compensation is further provided in the low-pass filter circuit 40. For example, the low-pass filter circuit 40 includes the phase compensation capacitor CC provided in parallel with the MOS capacitor CM between the gate of the output transistor TRQ and the second power supply node NS of VSS. The phase compensation capacitor CC has, for example, one end coupled to the node N2 of the drive voltage VD and the other end coupled to the second power supply node NS. The phase compensation capacitor CC is a high-voltage capacitor. For example, the withstand voltage of the phase compensation capacitor CC is higher than the withstand voltage of the MOS capacitor CM.

As the phase compensation capacitor CC, for example, an MIM (Metal-Insulator-Metal) capacitor, a high-voltage MOS capacitor, or the like can be used. For example, in a mode such as a test mode in which the analog switch SW is turned off, the analog switch SW is turned off and the MOS capacitor CM is not coupled to the node N2, and thereby, a situation that the phase margin can not be secured may occur. In this regard, the phase compensation capacitor CC is provided between the node N2 and the second power supply node NS as shown in FIG. 7, and thereby, the phase margin can be secured using the phase compensation capacitor CC in a mode such as the test mode in which the drive voltage VD is higher. Since the withstand voltage of the phase compensation capacitor CC is higher than the withstand voltage of the MOS capacitor CM, even when the node N2 of the drive voltage VD becomes a higher voltage in the test mode or the like, application of a high voltage exceeding the withstand voltage to the phase compensation capacitor CC can be prevented and the phase compensation capacitor CC can be protected.

As described above, the regulator circuit 30 of the embodiment includes the output transistor TRQ, the operational amplifier OP, and the low-pass filter circuit 40, for example, as shown in FIG. 1. The N-type output transistor TRQ is provided between the first power supply node ND and the output node NQ of the regulated voltage VREG, and the reference voltage VRF is input to the first input terminal and the feedback voltage VFB based on the regulated voltage VREG is input to the second input terminal of the operational amplifier OP. The low-pass filter circuit 40 outputs the drive voltage VD obtained by filtering the output voltage VQ of the operational amplifier OP to the gate of the output transistor TRQ. In the embodiment, the low-pass filter circuit 40 includes the MOS capacitor CM provided between the gate of the output transistor TRQ and the second power supply node NS, and including a low-voltage transistor having the withstand voltage lower than that of the high-voltage output transistor TRQ. According to the configuration, the low-pass filter circuit 40 is provided, and thereby, the noise reduction of the regulated voltage VREG can be realized. Further, the MOS capacitor CM having the low withstand voltage is used as the capacitor of the low-pass filter circuit 40, and thereby, the circuit area reduction can be realized. That is, both noise reduction and circuit area reduction can be realized. For example, a high-voltage transistor is used as the output transistor TRQ because VDD as a high voltage is applied to the drain or the like. On the other hand, since the N-type output transistor TRQ is source-follower coupled, the relationship of VD=VREG+VTH holds as shown in the expression (1), and the drive voltage VD of the node N2 can be made lower than that in the case of using a P-type output transistor. Thereby, in the embodiment, the low-voltage MOS capacitor CM is used as the capacitor of the low-pass filter circuit 40, and the circuit area is reduced compared to the case of using a high-voltage MOS capacitor CM.

As shown in FIG. 2, the low-pass filter circuit 40 includes the analog switch SW provided between the gate of the output transistor TRQ and the gate of the MOS capacitor CM. The analog switch SW is provided, and thereby, for example, even when the node N2 of the drive voltage VD becomes a high voltage, application of the high voltage to the low-voltage MOS capacitor CM can be prevented by turning off of the analog switch SW. As a result, the reliability and the like of the regulator circuit 30 can be improved.

In this case, the analog switch SW is, for example, the P-type transistor TRP as shown by A1 and A4 of FIG. 3. For example, instead of the N-type transistor TRN or the transmission gate TFG, the P-type transistor TRP is used as the analog switch SW. According to the configuration, deterioration of the operating point and noise of the regulator circuit 30 and deterioration of PSRR and the like due to the leakage current and the like in the analog switch SW can be suppressed. For example, in the transmission gate TFG, the leakage current is generated in two paths and the leakage current increases, however, the leakage current can be reduced using the one-side channel transistor as the P-type transistor TRP.

As shown by A4 in FIG. 3, the back gate of the P-type transistor TRP is coupled to the source. According to the configuration, the leakage current in the analog switch SW can be reduced. For example, the leakage current flowing from the node N2 of the drive voltage VD to the substrate can be reduced. Accordingly, deterioration of the performance of the regulator circuit 30 due to the leakage current can be suppressed.

The regulator circuit 30 has the normal operation mode and the test mode, and the analog switch SW is turned on in the normal operation mode and turned off in the test mode. According to the configuration, both noise reduction of the regulated voltage VREG and protection of the low-voltage MOS capacitor CM can be realized. For example, the analog switch SW is turned on in the normal operation mode, and thereby, the node N2 of the drive voltage VD and the MOS capacitor CM are electrically coupled and the RC low-pass filter circuit 40 including the resistor RF and the MOS capacitor CM is realized. Thus, noise reduction of the regulated voltage VREG can be realized. On the other hand, the analog switch SW is turned off in the test mode, and thereby, the node N2 of the drive voltage VD and the MOS capacitor CM are electrically blocked. As a result, even when the node N2 of the drive voltage VD becomes a high voltage, application of the high voltage to the MOS capacitor CM can be prevented and the MOS capacitor CM can be protected.

The regulated voltage is VREG, the gate-source voltage of the output transistor TRQ is VGS, the withstand voltage of the MOS capacitor CM is VMOS, and the withstand voltage of the analog switch is VSW. In this case, in the normal operation mode, the analog switch SW is turned on and VREG+VGS<VMOS is satisfied. In the test mode, the analog switch is turned off and VMOS<VREG+VGS<VSW is satisfied. As described above, in the normal operation mode in which the analog switch SW is turned on, the drive voltage VD=VREG+VGS becomes smaller than the withstand voltage VMOS of the MOS capacitor CM, and thereby, application of a voltage exceeding the withstand voltage to the gate of the MOS capacitor CM can be prevented, and the MOS capacitor CM can be protected. Further, in the test mode, the analog switch SW is turned off, and thereby, application of a high voltage to the MOS capacitor CM can be prevented. Further, VMOS<VREG+VGS<VSW holds, and thereby, application of the drive voltage VD=VREG+VGS exceeding the withstand voltage VSW to the analog switch SW can be prevented.

Further, the low-pass filter circuit 40 includes the phase compensation capacitor CC provided in parallel with the MOS capacitor CM between the gate of the output transistor TRQ and the second power supply node NS. According to the configuration, in a situation in which the drive voltage VD becomes high, even when the analog switch SW is turned off and the electrical coupling between the node N2 of the drive voltage VD and the MOS capacitor CM is blocked, the phase margin can be secured using the phase compensation capacitor CC.

The withstand voltage of the phase compensation capacitor CC is higher than the withstand voltage of the MOS capacitor CM. According to the configuration, even when the node N2 of the drive voltage VD becomes a high voltage, application of a voltage exceeding the withstand voltage to the phase compensation capacitor CC can be prevented, and the phase compensation capacitor CC can be protected.

Furthermore, the low-pass filter circuit 40 includes the resistor RF provided between the output terminal of the operational amplifier OP and the gate of the output transistor TRQ. The resistor RF is provided, and thereby, the RC low-pass filter circuit 40 including the resistor RF and the MOS capacitor CM can be realized, and noise reduction of the regulated voltage VREG can be realized.

The regulator circuit 30 includes the feedback circuit 50 provided between the output node NQ of the regulated voltage VREG and the second power supply node NS and outputting the feedback voltage VFB. According to the configuration, the operational amplifier OP compares the reference voltage VRF with the feedback voltage VFB, and controls the gate of the output transistor TRQ so that the feedback voltage VFB approaches the reference voltage VRF, for example. Accordingly, the regulator circuit 30 can output the regulated voltage VREG at a desired voltage.

The operational amplifier OP includes the transistor having the withstand voltage higher than the withstand voltage of the MOS capacitor CM. According to the configuration, even when the node N2 of the drive voltage VD becomes a high voltage, the voltage can be prevented from exceeding the withstand voltage of the operational amplifier OP, and the operational amplifier OP can be protected.

### 2. Circuit Device and Oscillator

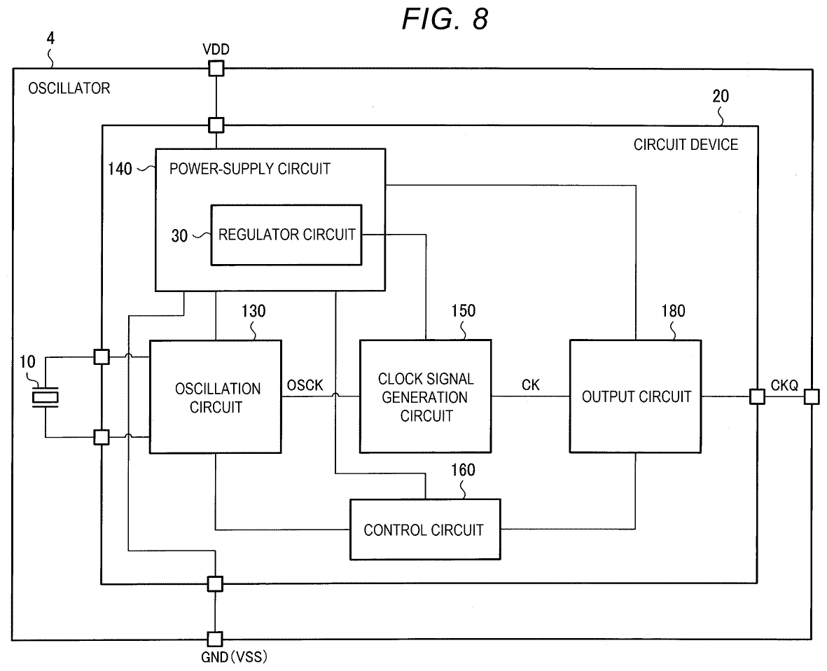

FIG. 8 shows a configuration example of a circuit device 20 of the embodiment and an oscillator 4 including the circuit device 20. The circuit device 20 includes the regulator circuit 30 of the embodiment. For example, the circuit device 20 includes a power supply circuit 140, and the regulator circuit 30 is provided in the power supply circuit 140. The oscillator 4 of the embodiment includes the circuit device 20 and a resonator 10. For example, in FIG. 8, the resonator 10 is electrically coupled to the circuit device 20. For example, the resonator 10 and the circuit device 20 are electrically coupled using an internal wiring, a bonding wire, or a metal bump of a package that houses the resonator 10 and the circuit device 20.

The resonator 10 is an element that generates mechanical resonation by an electrical signal. For example, the resonator 10 can be implemented by a resonator element such as a quartz crystal resonator element. For example, the resonator 10 can be implemented by a quartz crystal resonator element that performs thickness-shear resonation at a cut angle of AT cut or SC cut, a tuning fork type quartz crystal resonator element, a double-tuning fork type quartz crystal resonator element, or the like. For example, the resonator 10 may be a resonator provided in an SPXO (Simple Packaged Crystal Oscillator), or may be a resonator provided in a temperature compensated crystal oscillator (TCXO) having no thermostatic oven or a resonator provided in an oven-controlled quartz crystal oscillator (OCXO) having a thermostatic oven. Note that the resonator 10 of the embodiment can be implemented by various resonator elements such as a resonator element other than the thickness-shear resonation type, the tuning fork type, or the double-tuning fork type resonator element, or a piezoelectric resonator element formed using a material other than quartz crystal. For example, a SAW (Surface Acoustic Wave) resonator, an MEMS (Micro Electro Mechanical Systems) resonator as a silicon resonator formed using a silicon substrate, or the like can be employed as the resonator 10.

The circuit device 20 includes an oscillation circuit 130, the power supply circuit 140, a clock signal generation circuit 150, a control circuit 160, and an output circuit 180. Each pad as a terminal of the circuit device 20 is electrically coupled to an external coupling terminal of the oscillator 4. For example, the respective pads of VDD, GND, and CKQ are electrically coupled to the respective corresponding external coupling terminals. Note that the circuit device 20 is not limited to the configuration in FIG. 8, but various modifications such that a part of the component elements is omitted, another component element is added, and the component element is changed to another type of component element can be made.

The oscillation circuit 130 is a circuit that oscillates the resonator 10. For example, the oscillation circuit 130 generates an oscillation signal by oscillating the resonator 10. For example, the oscillation circuit 130 can be implemented by an oscillation drive circuit electrically coupled to one end and the other end of the resonator 10 and a passive element such as a capacitor or a resistor. The drive circuit can be implemented by, for example, a CMOS inverter circuit or a bipolar transistor. The drive circuit is a core circuit of the oscillation circuit 130, and d the drive circuit voltage-drives or current-drives the resonator 10 to oscillate the resonator 10. As the oscillation circuit 130, various types of oscillation circuits such as an inverter type, a Pierce type, a Colpitts type, or a Hartley type can be used. Note that the coupling in the embodiment is electrical coupling. The electrical coupling is coupling by which an electrical signal can be transmitted and information can be transmitted through the electrical signal. The electrical coupling may be coupling through a passive element or the like.

The power supply circuit 140 is supplied with power supply voltages VDD as the power supply voltage and VSS (GND), generates various power supply voltages for the internal circuit of the circuit device 20, and supplies the voltages to the respective circuits. For example, the power supply circuit 140 generates various regulated voltages obtained by stepping down of the power supply voltage VDD, and supplies the voltages to the respective circuits of the circuit device 20. For example, the power supply circuit 140 includes a reference voltage generation circuit such as a bandgap reference circuit, and the reference voltage generation circuit generates the reference voltage VRF described with reference to FIGS. 1, 2, etc. Further, the power supply circuit 140 includes the regulator circuit 30, and the regulated voltage VREG from the regulator circuit 30 is supplied to, for example, the clock signal generation circuit 150. Note that the power supply circuit 140 may include, for example, another regulator circuit than the regulator circuit 30, and the other regulator circuit may generate, for example, a regulated voltage serving as a power supply voltage for the oscillation circuit 130 and the control circuit 160.

The clock signal generation circuit 150 generates a clock signal CK based on an oscillation clock signal OSCK from the oscillation circuit 130. For example, the clock signal generation circuit 150 generates the clock signal CK using the oscillation clock signal OSCK as a reference clock signal. The clock signal CK is, for example, a clock signal having a frequency obtained by multiplication of the frequency of the oscillation clock signal OSCK. The clock signal CK is, for example, a clock signal synchronized in phase with the oscillation clock signal OSCK. According to the configuration, the clock signal generation circuit 150 can generate the clock signal CK based on the oscillation clock signal OSCK with high frequency accuracy from the oscillation circuit 130. Then, the circuit device 20 and the oscillator 4 can output the output clock signal CKQ based on the clock signal CK.

Specifically, the clock signal generation circuit 150 operates based on the regulated voltage VREG from the regulator circuit 30, and generates the clock signal CK having a frequency obtained by multiplying the frequency of the oscillation clock signal OSCK. For example, the clock signal generation circuit 150 operates using the regulated voltage VREG as a power supply voltage, and generates the clock signal CK based on the oscillation clock signal OSCK. For example, a circuit such as a voltage controlled oscillation circuit of the clock signal generation circuit 150 operates using the regulated voltage VREG as a power supply voltage. According to the configuration, the clock signal generation circuit 150 operates based on the low-noise regulated voltage VREG generated by the regulator circuit 30 of the embodiment, and thereby, can generate the clock signal CK. As a result, noise reduction of the clock signal CK generated by the clock signal generation circuit 150 can be realized, and, for example, the clock signal CK with reduced phase jitter or the like can be generated.

The clock signal generation circuit 150 includes a circuit including a transistor having a withstand voltage lower than the withstand voltage of the output transistor TRQ of the regulator circuit 30 and operating based on the regulated voltage VREG. For example, a circuit such as a voltage controlled oscillation circuit of the clock signal generator 150 includes a transistor having a withstand voltage lower than the withstand voltage of the output transistor TRQ. For example, the output transistor TRQ is a transistor having a first withstand voltage, and the circuit of the clock signal generator 150 includes a transistor having a second withstand voltage lower than the first withstand voltage. According to the configuration, the circuit supplied with the regulated voltage VREG and operating in the clock signal generation circuit 150 includes the transistor having the low withstand voltage, and thus, for example, high-speed operation can be performed and power consumption can be reduced. Further, since the circuit of the clock signal generation circuit 150 operates by the low-noise regulated voltage VREG, the noise of the generated clock signal CK can also be reduced.

The control circuit 160 is a logic circuit and performs various kinds of control processing and arithmetic processing. For example, the control circuit 160 controls the entire circuit device 20 and controls the operation sequence of the circuit device 20. The control circuit 160 performs various kinds of processing for controlling the oscillation circuit 130. The control circuit 160 can be implemented by a circuit of an ASIC (Application Specific Integrated Circuit) by automatic placement and wiring such as a gate array. The control circuit 160 may perform temperature compensation processing. For example, the control circuit 160 performs temperature compensation processing based on a temperature detection result of a temperature sensor. Thereby, the oscillator 4 such as a TCXO can be realized. In this case, a variable capacitance circuit having capacitance controlled based on the result of the temperature compensation processing may be provided in the oscillation circuit 130.

The output circuit 180 buffers the clock signal CK from the clock signal generation circuit 150 and outputs the output clock signal CKQ. The output clock signal CKQ serves as an external output clock signal of the oscillator 4. The output circuit 180 outputs the output clock signal CKQ when an output enable signal is active, for example. The output enable signal can be input from outside via an external coupling terminal, for example.

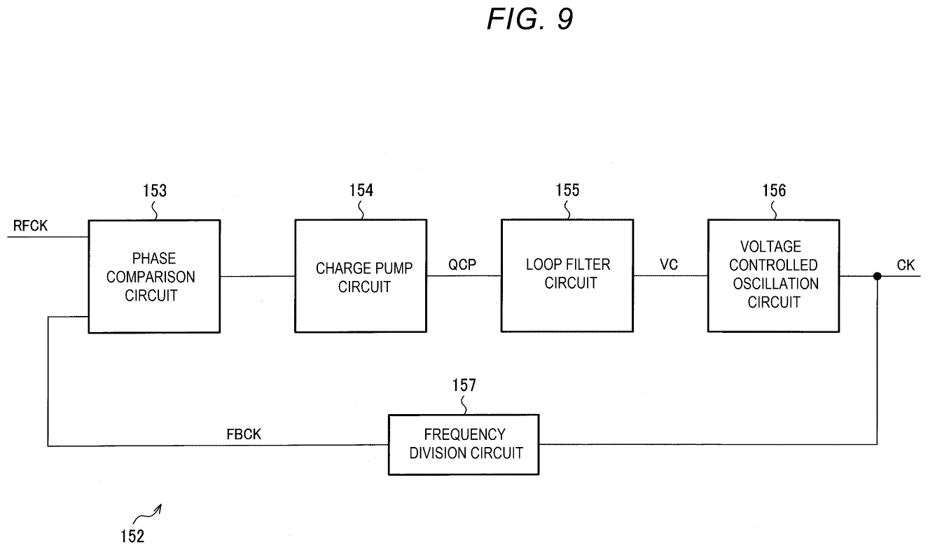

FIG. 9 shows a configuration example of a PLL circuit 152 which is an example of the clock signal generation circuit 150. The PLL circuit 152 includes a phase comparison circuit 153, a charge pump circuit 154, a loop filter circuit 155, a voltage controlled oscillation circuit 156, and a frequency division circuit 157. The charge pump circuit 154 and the loop filter circuit 155 form a control voltage generation circuit. The PLL circuit 152 is not limited to the configuration, but various modifications such that a part of the component elements is omitted, another component element is added, and a part of the component elements is replaced by another component element can be made.

The phase comparison circuit 153 performs phase comparison between a reference clock signal RFCK and a feedback clock signal FBCK. The reference clock signal RFCK is, for example, the oscillation clock signal OSCK. For example, the phase comparison circuit 153 compares the phase of the reference clock signal RFCK with the phase of the feedback clock FBCK, signal and outputs a signal corresponding to the phase difference between the reference clock signal RFCK and the feedback clock signal FBCK as a phase comparison result signal. For example, an up signal and a down signal are output as phase comparison result signals. The charge pump circuit 154 performs a charge pump operation based on the phase comparison result signal from the phase comparison circuit 153, and the loop filter circuit 155 performs filter processing on the output signal QCP of the charge pump circuit 154. Thereby, a control voltage VC for controlling the oscillation of the voltage controlled oscillation circuit 156 is generated. The voltage controlled oscillation circuit 156 as a VCO (Voltage controlled oscillator) generates the clock signal CK having a frequency corresponding to the control voltage VC. For example, the voltage controlled oscillation circuit 156 performs an oscillation operation based on the control voltage VC to generate the clock signal CK. As the voltage controlled oscillation circuit 156, for example, an LC oscillation circuit using an inductor can be used.

The frequency division circuit 157 divides the frequency of the clock signal CK and outputs the feedback clock signal FBCK. For example, the frequency division circuit 157 outputs a signal having a frequency obtained by division of the frequency of the clock signal CK by a division ratio set by a division ratio setting value as the feedback clock signal FBCK. For example, a fractional frequency division circuit may be realized as the frequency division circuit 157 by using digital sigma modulation. For example, when the frequency of the oscillation of the voltage controlled oscillation circuit 156 is fvco and the frequency division ratio of the frequency division operation of the frequency division circuit 157 is DIV, the frequency of the feedback clock signal FBCK is fvco/DIV. The phase comparison circuit 153 compares the phase of the reference clock signal RFCK with the phase of the feedback clock signal FBCK from the frequency division circuit 157.

For example, the PLL circuit 152 in FIG. 9 generates a clock signal CK having a high frequency of, for example, 1 GHz or more by using an LC oscillation circuit as the voltage controlled oscillation circuit 156. As described above, the voltage controlled oscillation circuit 156 of the PLL circuit 152 or the like is required to operate at a high frequency, and includes a low-voltage transistor that can perform high-speed operation. Therefore, the regulator circuit 30 generates the regulated voltage VREG obtained by stepping down of the power supply voltage VDD, and circuit such as the voltage controlled oscillation circuit 156 of the PLL circuit 152 operates with the regulated voltage VREG lower than that of the power supply voltage VDD as the power supply voltage. On the other hand, for example, in the test mode, a voltage exceeding the withstand voltage of a low-voltage transistor may be applied to each circuit of the PLL circuit 152 for a screening test or the like. In this case, the drive voltage VD also becomes a high voltage, and the high voltage is input to the gate of the MOS capacitor CM. Also in this case, for example, in FIG. 2 and FIG. 7, the analog switch SW is provided and the analog switch SW is turned off in the test mode, and thereby, application of a high voltage to the gate of the MOS capacitor CM is prevented.

As described above, the regulator circuit of the embodiment includes the N-type output transistor provided between the first power supply node and the output node of the regulated voltage, the operational amplifier having the first input terminal to which the reference voltage is input and the second input terminal to which the feedback voltage based on the regulated voltage is input, and the low-pass filter circuit outputting the drive voltage obtained by filtering of the output voltage of the operational amplifier to the gate of the output transistor. The low-pass filter circuit includes the MOS capacitor provided between the gate of the output transistor and the second power supply node and including a transistor having the withstand voltage lower than that of the output transistor.

According to the configuration, the low-pass filter circuit is provided, and thereby, noise reduction of the regulated voltage can be realized. Further, the MOS capacitor having the low withstand voltage is used as the capacitor of the low-pass filter circuit, and thereby, the circuit area reduction can be realized.

In the embodiment, the low-pass filter circuit may include the analog switch provided between the gate of the output transistor and the gate of the MOS capacitor.

With the analog switch, even when the node of the drive voltage is at a high voltage, application of the high voltage to the MOS capacitor by turning off of the analog switch can be prevented.

In the embodiment, the analog switch may be a P-type transistor.

According to the configuration, deterioration of the performance of the regulator circuit due to the leakage current or the like in the analog switch can be suppressed.

In the embodiment, the back gate of the P-type transistor may be coupled to the source.

According to the configuration, the leakage current in the analog switch can be reduced, and the deterioration of the performance of the regulator circuit due to the leakage current can be suppressed.

In the embodiment, the regulator circuit may have the normal operation mode and the test mode, and the analog switch may be turned on in the normal operation mode and turned off in the test mode.

According to the configuration, both noise reduction of the regulated voltage in the normal operation mode and protection of the MOS capacitor in the test mode can be realized.

Further, in the embodiment, the regulator circuit has the normal operation mode and the test mode, the regulated voltage is VREG, the gate-source voltage of the output transistor is VGS, the withstand voltage of the MOS capacitor is VMOS, and the withstand voltage of the analog switch is VSW. Here, in the normal operation mode, the analog switch may be turned on and VREG+VGS<VMOS may be satisfied, and in the test mode, the analog switch may be turned off and VMOS<VREG+VGS<VSW may be satisfied.

According to the configuration, in the normal operation mode, the drive voltage is smaller than the withstand voltage of the MOS capacitor, and thereby, the MOS capacitor can be protected. Further, in the test mode, the analog switch is turned off, and thereby, application of a high voltage to the MOS capacitor is prevented and application of a drive voltage exceeding the withstand voltage to the analog switch can be prevented.

In the embodiment, the low-pass filter circuit may include the phase compensation capacitor provided in parallel with the MOS capacitor between the gate of the output transistor and the second power supply node.

According to the configuration, even when the analog switch is turned off and the electrical coupling between the node of the drive voltage and the MOS capacitor is blocked, the phase margin or the like can be secured using the phase compensation capacitor.

In the embodiment, the withstand voltage of the phase compensation capacitor may be higher than the withstand voltage of the MOS capacitor.

According to the configuration, even when the node of the drive voltage becomes a high voltage, application of a voltage exceeding the withstand voltage to the phase compensation capacitor can be prevented.

In the embodiment, the low-pass filter circuit may include the resistor provided between the output terminal of the operational amplifier and the gate of the output transistor.

Such the resistor is provided, and thereby, the RC low-pass filter circuit including the resistor and the MOS capacitor can be realized.

In the embodiment, the feedback circuit provided between the output node of the regulated voltage and the second power supply node and outputting the feedback voltage may be provided.

According to the configuration, the operational amplifier compares the reference voltage with the feedback voltage, for example, controls the gate of the output transistor so that the feedback voltage approaches the reference voltage, and can output the regulated voltage at a desired voltage.

In the embodiment, the operational amplifier may include the transistor having the withstand voltage higher than the withstand voltage of the MOS capacitor.

According to the configuration, even when the node of the drive voltage becomes a high voltage, the voltage can be prevented from exceeding the withstand voltage of the operational amplifier, and the operational amplifier can be protected.

In addition, the embodiment relates to the circuit device including the power supply circuit including the above described regulator circuit, the oscillation circuit oscillating the resonator, and the clock signal generation circuit generating the clock signal based on the oscillation clock signal from the oscillation circuit.

According to the configuration, the clock signal generation circuit can generate the clock signal based on the oscillation clock signal with high frequency accuracy from the oscillation circuit.

Further, in the embodiment, the clock signal generation circuit may operate based on the regulated voltage from the regulator circuit and generate the clock signal having the frequency obtained by multiplying the frequency of the oscillation clock signal.

According to the configuration, the clock signal generation circuit operates based on the low-noise regulated voltage generated by the regulator circuit, and can generate the clock signal.

In the embodiment, the clock signal generation circuit may include the circuit including the transistor having the withstand voltage lower than the withstand voltage of the output transistor and operates based on the regulated voltage.

According to the configuration, the circuit supplied with the regulated voltage and operating in the clock signal generation circuit includes the transistor having the low withstand voltage, and thus, for example, high-speed operation can be performed and power consumption can be reduced.

The embodiment also relates to the oscillator including the above described circuit device and the resonator.

While the embodiment has been described in detail above, a person skilled in the art can readily understand that many modifications can be made without substantially departing from the novel matters and effects of the present disclosure. Therefore, all the modifications are within the scope of the present disclosure. For example, in the specification or the drawings, the terms described with different terms in the broader sense or synonymous terms at least once may be replaced by the different terms in any part of the specification or the drawings. All combinations of the embodiment and the modifications are also within in the scope of the present disclosure. The configurations, operations, and the like of the regulator circuit, the circuit device, and the oscillator are not limited to those described in the embodiment, but various modifications can be made.

What is claimed is:

1. A regulator circuit comprising:
an N-type output transistor provided between a first power supply node and an output node of a regulated voltage;
an operational amplifier having a first input terminal to which a reference voltage is input and a second input terminal to which a feedback voltage based on the regulated voltage is input; and
a low-pass filter circuit outputting a drive voltage obtained by filtering an output voltage of the operational amplifier to a gate of the output transistor, wherein
the low-pass filter circuit includes a MOS capacitor provided between the gate of the output transistor and a second power supply node and including a transistor having a withstand voltage lower than that of the output transistor.

2. The regulator circuit according to claim 1, wherein
the low-pass filter circuit includes an analog switch provided between the gate of the output transistor and a gate of the MOS capacitor.

3. The regulator circuit according to claim 2, wherein
the analog switch is a P-type transistor.

4. The regulator circuit according to claim 3, wherein
a back gate of the P-type transistor is coupled to a source.

5. The regulator circuit according to claim 2, wherein
a normal operation mode and a test mode are provided, and
the analog switch is turned on in the normal operation mode and turned off in the test mode.

6. The regulator circuit according to claim 2, wherein
a normal operation mode and a test mode are provided, and
when the regulated voltage is VREG, a gate-source voltage of the output transistor is VGS, a withstand voltage of the MOS capacitor is VMOS, and a withstand voltage of the analog switch is VSW, the analog switch is turned on and VREG+VGS<VMOS in the normal operation mode, and the analog switch is turned off and VMOS<VREG+VGS<VSW in the test mode.

7. The regulator circuit according to claim 1, wherein
the low-pass filter circuit includes a phase compensation capacitor provided in parallel with the MOS capacitor between the gate of the output transistor and the second power supply node.

8. The regulator circuit according to claim 7, wherein
a withstand voltage of the phase compensation capacitor is higher than a withstand voltage of the MOS capacitor.

9. The regulator circuit according to claim 1, wherein
the low-pass filter circuit includes a resistor provided between an output terminal of the operational amplifier and the gate of the output transistor.

10. The regulator circuit according to claim 1, further comprising a feedback circuit provided between the output node of the regulated voltage and the second power supply node and outputting the feedback voltage.

11. The regulator circuit according to claim 1, wherein
the operational amplifier includes a transistor having a withstand voltage higher than a withstand voltage of the MOS capacitor.

12. A circuit device comprising:
a power supply circuit including the regulator circuit according to claim 1;
an oscillation circuit oscillating a resonator; and
a clock signal generation circuit generating a clock signal based on an oscillation clock signal from the oscillation circuit.

13. The circuit device according to claim 12, wherein
the clock signal generation circuit operates based on the regulated voltage from the regulator circuit, and generates a clock signal having a frequency obtained by multiplying a frequency of the oscillation clock signal.

14. The circuit device according to claim 12, wherein
the clock signal generation circuit includes a circuit including a transistor having a withstand voltage lower than a withstand voltage of the output transistor and operating based on the regulated voltage.

15. An oscillator comprising:
the circuit device according to claim 12; and
the resonator.
